(19) United States
(12) Patent Application Publication
(10) Pub. No.: US 2013/0256271 A1
(43) Pub. Date: Oct. 3, 2013

(54) METHODS AND APPARATUSES FOR CONTROLLING PLASMA IN A PLASMA PROCESSING CHAMBER

(71) Applicants: Theodoros Panagopoulos, San Jose, CA (US); John Holland, San Jose, CA (US); Alex Paterson, San Jose, CA (US)

(72) Inventors: Theodoros Panagopoulos, San Jose, CA (US); John Holland, San Jose, CA (US); Alex Paterson, San Jose, CA (US)

(21) Appl. No.: 13/438,824

(22) Filed: Apr. 3, 2012

(51) Int. Cl. H01L 21/3065

(52) U.S. Cl. 216/68; 156/345.35

(57) ABSTRACT

Methods and apparatus for controlling plasma in a plasma processing system having at least an inductively coupled plasma (ICP) processing chamber are disclosed. The ICP chamber employs at least a first/center RF coil, a second/edge RF coil disposed concentrically with respect to the first/center RF coil, and a RF coil set having at least a third/mid RF coil disposed concentrically with respect to the first/center RF coil and the second/edge RF coil in a manner such that the third/mid RF coil is disposed in between the first/center RF coil and the second/edge RF coil. During processing, RF currents in the same direction are provided to the first/center RF coil and the second/edge RF coil while RF current in the reverse direction (relative to the direction of the currents provided to the first/center RF coil and the second/edge RF coil) is provided to the third/mid RF coil.

### BACKGROUND OF THE INVENTION

Plasma has long been employed for processing substrates (e.g., wafers, flat panel displays, liquid crystal displays, etc.) into electronic devices (e.g., integrated circuit dies) for incorporation into a variety of electronic products (e.g., smart phones, computers, etc.).

In plasma processing, a plasma processing system having one or more plasma processing chambers may be employed to process one or more substrates. In each chamber, plasma generation may employ capacitively coupled plasma technology, inductively coupled plasma technology, electron-cyclotron technology, microwave technology, etc.

Inductively coupled plasma technology tends to produce dense plasma suitable for etching high performance devices and is thus widely employed. In a typical inductively coupled plasma (ICP) system, RF energy is provided to an antenna, typically in the form of an inductive coil disposed above a dielectric window, which is in turn disposed above a substrate to be processed. During the processing of a wafer, for example, the substrate is disposed on a work piece holder (typically an electrostatic chuck or another type of chuck) and reactant gas (which may employ one or a mixture of multiple types of gases) may be released into the plasma processing region above the substrate. The RF energy couples to the reactant gas through a dielectric window to ignite and sustains a plasma suitable for substrate processing.

It has been found, however, that the plasma flux formed from the inductive coil tends to assume a donut shape above the substrate due to localized high magnetic flux profile induced by the coil. Accordingly, there is a certain degree of process non-uniformity (with respect to, for example, etch rate or etch depth) from the center of the substrate to the edge of the substrate. In the prior art, multiple concentric coils have been employed to alleviate the process non-uniformity inherently introduced by the use of inductive coils. For example, the use of two concentric inductive coils has been attempted in the prior art with varying degrees of success.

To elaborate, FIG. 1A shows a simplified diagram of a cut-away side view of prior art ICP chamber 102 having two concentric coils 104 and 106. Coils 104 and 106 are disposed above dielectric window 108 and powered by respective RF power supplies 110 and 112. The two coils 104 and 106 are shown more clearly in the example of FIG. 113.

In FIG. 1A, the plasma cloud is shown by reference number 126. As can be seen in FIG. 1A, magnetic flux lines 122 form localized dense magnetic flux region 124 where plasma 126 is ignited and sustained for processing substrate 130. Since FIG. 1A is a cut-away side view, it should be understood that this plasma 126 is donut-shaped above substrate 130 if viewed from the top of FIG. 1A. This donut-shaped profile of plasma 126 results in process non-uniformity from the center of substrate 130 to the edge of substrate 130.

In the prior art, different RF power levels are supplied to the two coils in an attempt to address the aforementioned process non-uniformity issue.

FIG. 1C illustrates the effect of supplying high RF power to center coil 162 via RF power supply 160 and supplying low RF power to edge coil 166 via RF power supply 164. In this case, the donut-shaped plasma cloud 168 tends to be formed under center coil 162 as shown.

FIG. 1D illustrates the effect of supplying the same amount of RF power to center coil 172 and edge coil 176 (by RF power supplies 170 and 174 respectively). In this case, the donut-shaped plasma cloud 178 tends to be formed under the dielectric window approximately equidistant from the two coils 172 and 176 as shown.

FIG. 1E illustrates the effect of supplying low RF power to center coil 182 via RF power supply 180 and supplying high RF power to edge coil 186 via RF power supply 184. In this case, the donut-shaped plasma cloud 188 tends to be formed under edge coil 188 as shown.

As can be seen in FIGS. 1C-1E, although the use of multiple coils by the prior art provides some degree of tunability to the plasma, the process non-uniformity issue remains. In all three FIGS. 1C-1E, a significant difference in plasma flux exists from the center of the substrate to the edge of the substrate.

Reducing process non-uniformity in ICP systems is one among many goals of embodiments of the methods and apparatuses of the present invention.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1A and FIG. 1B show a simplified diagram of a cut-away side view of prior art ICP chamber having two concentric coils to facilitate discussion.

FIG. 1C illustrates the effect of supplying high RF power to the center coil and supplying low RF power to the edge coil.

FIG. 1D illustrates the effect of supplying the same amount of RF power to the center coil and the edge coil.

FIG. 1E illustrates the effect of supplying low RF power to the center coil and supplying high RF power to the edge coil.

FIGS. 2A and 2B show a simplified representation of the cut-away side view of relevant components of an ICP chamber of a plasma processing system (which may have multiple chambers of the same or different types) having a mid coil set.

FIG. 2C shows in a conceptual manner the effect of providing third/mid RF coil a counter RF current, which is in opposite direction with the RF currents supplied to first/center RF coil and second/edge RF coil.

FIGS. 3A1 and 3A2 illustrate the effect on the plasma when the RF power level to the third/mid RF coil is relatively low compared to the RF power level provided to the first/center RF coil and second/edge RF coil.

FIGS. 3B1 and 3B2 illustrate the effect on the plasma when the RF power level to the third/mid RF coil is at roughly the same power level compared to the RF power level provided to the first/center RF coil and second/edge RF coil.

FIGS. 3C1 and 3C2 illustrate the effect on the plasma when the RF power level to the third/mid RF coil is relatively high compared to the RF power level provided to the first/center RF coil and second/edge RF coil.

FIG. 4 shows, in accordance with an embodiment, a method for adjusting the power deposition profile in an ICP chamber.

FIG. 5 shows a simplified diagram of an ICP chamber which employs sensor measurements of chamber parameters reflecting localized ion fluxes as feedback signals to automatically change the RF currents provided to the mid RF coil and/or center RF coil and/or edge RF coil.

FIG. 6A shows an example where the mid RF coil (third RF coil 604) is substantially taller than the center RF coil and/or with the edge RF coil

FIG. 6B shows an example where the mid RF coil is non-coplanar with the center RF coil and/or with the edge RF coil.

FIG. 6C shows an example where the mid RF coil is non-coplanar with the center RF coil and/or with the edge RF coil.

FIG. 6D shows an example where the mid RF coil is not disposed equidistant from the center RF coil and/or the edge RF coil.

FIG. 6E shows an example where the mid RF coil is non-coplanar with the center RF coil and/or with the edge RF coil and some overlapping exists between the mid RF coil and the center RF coil and/or with the edge RF coil.

FIG. 6F shows an example where the mid RF coil is a solenoid-wound coil while center RF coil and/or edge RF coil are planar coils.

FIG. 6G shows an example where the mid RF coil is a planar coil while center RF coil and/or edge RF coil are solenoid-wound coils.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described hereinbelow, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to methods and apparatus for controlling plasma in a plasma processing system having at least an inductively coupled plasma (ICP) processing chamber. In one or more embodiments, the inductively coupled plasma processing chamber includes a work piece holder, e.g., an electrostatic chuck, for supporting the substrate during plasma processing. The electrostatic chuck and the substrate are disposed in a chamber having an upper dielectric window. Above the dielectric window, there is disposed at least a first/center RF coil, a second/edge RF coil disposed concentrically with respect to the first/center RF coil, and a RF coil set having at least a third/mid RF coil disposed concentrically with respect to the first/center RF coil and the second/edge RF coil in a manner such that the third/mid RF coil is disposed in between the first/center RF coil and the second/edge RF coil. During processing, RF currents in the same direction are provided to the first/center RF coil and the second/edge RF coil while RF current in the reverse direction (relative to the direction of the currents provided to the first/center RF coil and the second/edge RF coil) is provided to the third/mid RF coil. For example, the RF current provided to the first/center RF coil and the second/edge RF coil may be clockwise when viewed from the top of the chamber, while the RF current provided to the third/mid RF coil may be counter-clockwise. Alternatively, the RF current provided to the first/center RF coil and the second/edge RF coil may be counter-clockwise when viewed from the top of the chamber, while the RF current provided to the third/mid RF coil may be clockwise

In one or more embodiments, the first/center RF coil, the second/edge. RF coil, and the third/mid RF coils are all coplanar with respect to one another. In one or more embodiments, the first/center RF coil and the second/edge RF coil are co-planar whereby the third/mid RF coil is non-coplanar with respect to the first/center RF coil and the second/edge RF coil. In one or more embodiments, the first/center RF coil and the second/edge RF coil are non-coplanar, with the third/mid RF coil coplanar with either the first/center RF coil or the second/edge RF coil. In one or more embodiments, the first/center RF coil, the second/edge RF coil, and the third/mid RF coils are all non-coplanar with respect to one another.

In one or more embodiments, the third/mid RF coil itself is a non-planar coil. In other words, the coils of the third/mid RF coil do not all reside in the same spatial plane. In one or more embodiments, the third/mid RF coil is a solenoid-wound coil. In one or more embodiments, the third/mid RF coil is a planar coil while the first/center RF coil and/or the second/edge RF coil are/is non-planar.

In one or more embodiments, the third/mid RF coil is a planar coil while the first/center RF coil and/or the second/edge RF coil are/is solenoid wound.

In one or more embodiments, the third/mid RF coil is disposed closer to the plane of the dielectric window than the first/center RF coil and/or the second/edge RF coil. In one or more embodiments, the third/mid RF coil is disposed further way from the plane of the dielectric window than the first/center RF coil and/or the second/edge RF coil.

In one or more embodiments, the RF coil set that includes the third/mid RF coil consists of only a single concentric coil—i.e., the third/mid RF coil. Alternatively, in one or more embodiments, the RF coil set that includes the third/mid RF coil comprises a plurality of concentric RF coils. In one or more embodiments, the multiple RF coils in the RF coil set that includes the third/mid RF coil all carry RF currents flowing in the same direction. In one or more embodiments, the current(s) flowing through the coil/coils in one subset of the RF coil set that includes the third/mid RF coil may flow in the same direction as the RF current, flowing in the first and second/edge RF coil while the current(s) flowing through the coil/coils in another subset of the RF coil set that includes the third/mid RF coil may flow in the opposite direction as the RF current flowing in the first and second/edge RF coil. It is contemplated that this arrangement is particularly advantageous for extremely large substrates (above 300 mm, for example) that may require multiple concentric coils (e.g., 3, 4, 5, 6, 7, 8, 9, or more) having alternate current directions to more effectively even out the power deposition profile across the wafer surface.

In one or more embodiments, the ICP chambers may include a sensor set comprising one or more sensors configured to measure a chamber parameter that reflects the localized plasma densities at different locations above the substrate. For example, a thin wire Langmuir probe responsive to the local plasma density, a planar ion flux probe responsive to the thermal energy created by the ion flux or a plasma resonance probe responsive to the local electron density may be employed to determine the localized plasma densities at different locations above the substrate. The sensor set may comprise a single movable sensors (e.g., movable vertically or laterally or rotationally) to measure the chamber parameter reflective of the plasma density at different locations above the substrate. Alternatively, the sensor set may comprise multiple sensors disposed at fixed locations throughout the chamber or attached to or embedded in various chamber components to measure one or more chamber parameters reflective of the plasma density at different positions above the substrate.

In one or more embodiments, the sensor measurements may be employed as feedback signals to vary the RF power to the third/mid RF coil, to vary the phase of the third/mid RF coil, or to change the position of the third/mid RF coil relative to the second/edge RF coil and the first/center RF coil in order to, improve the power deposition profile so as to avoid undue localized power deposition over one part of the substrate and thus improving process uniformity across the substrate surface. Power level and/or phase changes may be accomplished by sending the appropriate control signal(s) to the RF power supply/supplies while position changes may be accomplished by sending an appropriate signal to an actuator (such as pneumatic, hydraulic, mechanical, electrical, electro-mechanical, magnetic, etc.) coupled to an RF coil. In one or more embodiments, the sensor measurements may be employed as feedback signals to vary the RF power to the various RF coils, to vary the phase to the various coils, or to change the relative positions of the various RF coils in order to improve the power deposition profile so as to avoid undue localized power deposition over one part of the substrate and thus improving process uniformity across the substrate surface.

In one or more particularly advantageous embodiments, the change/changes in RF power, phase, and/or position (whether solely relating to the third/mid RF coil and/or to multiple RF coils including at least one of the first/center RF coil and the second/edge RF coil) is/are made automatically in-situ while substrate processing is taking place on the same substrate. In other words, the substrate may be processed initially with a given RF coil provided with a given RF power level and/or a given phase and/or a given position relative to other RF coils and/or relative to the dielectric window. Responsive to, for example, sensor measurements, the RF power level and/or the phase and/or the position of the RF coil(s) may change while processing on the same substrate is still taking place in the same chamber.

As the term is referred to herein, “automatic” or “automatically” refers to the fact that such change is made responsive to analog and/or digital control signal(s), which is/are generated algorithmically by software and/or by dedicated logic circuitry in response to measurements from the sensor set and such change is made without requiring human operator initiation for every change. In some cases, human consent may be obtained before a change is implemented but the determination whether change is needed and/or how much change is needed and/or what change is needed are/is still made without requiring explicit human involvement. As mentioned earlier, one advantageous aspect of one or more embodiments refers to the fact that the change is made in-situ responsive to sensor measurements to adjust the plasma while a substrate is processed. Alternatively or additionally, processing may be performed on test substrates and the chamber may be tuned by changing the RF power, phase, and/or position (whether solely relating to the third/mid RF coil and/or to multiple RF coils including at least one of the first/center RF coil and the second/edge RF coil) responsive to metrology measurements on the test substrate(s) in order to improve process uniformity.

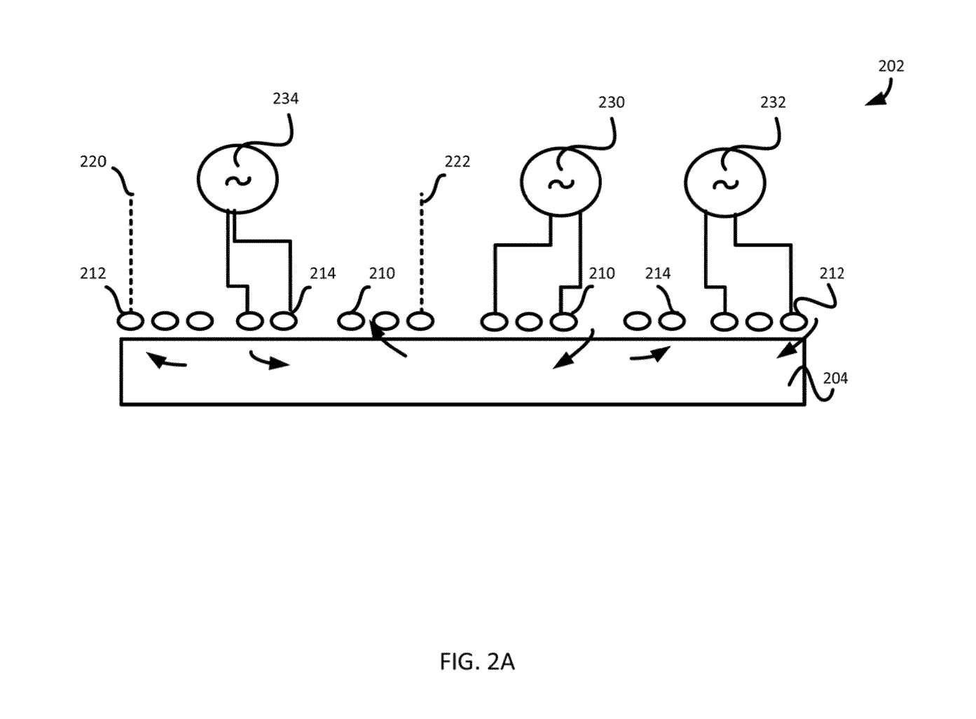

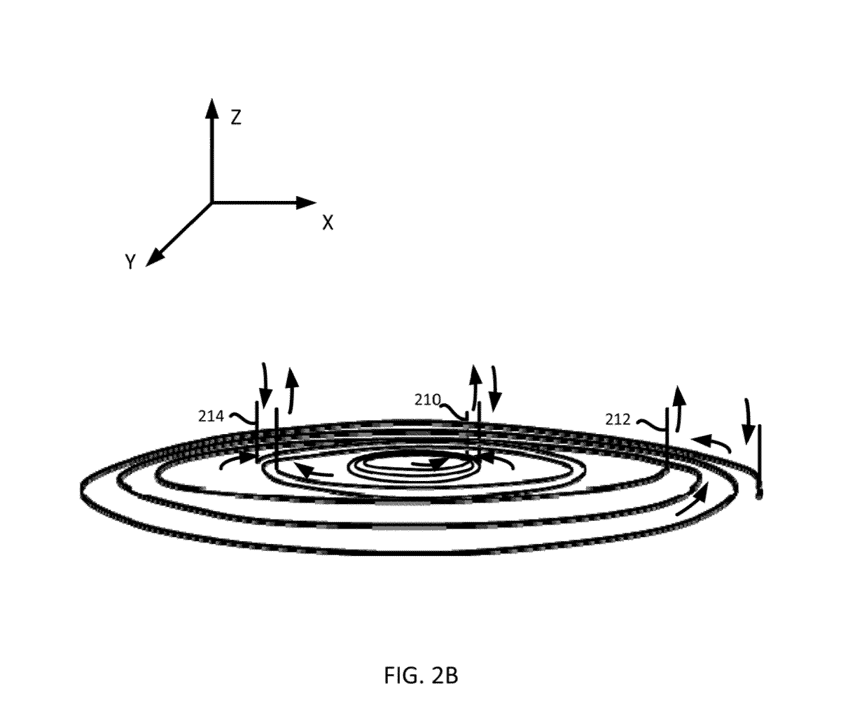

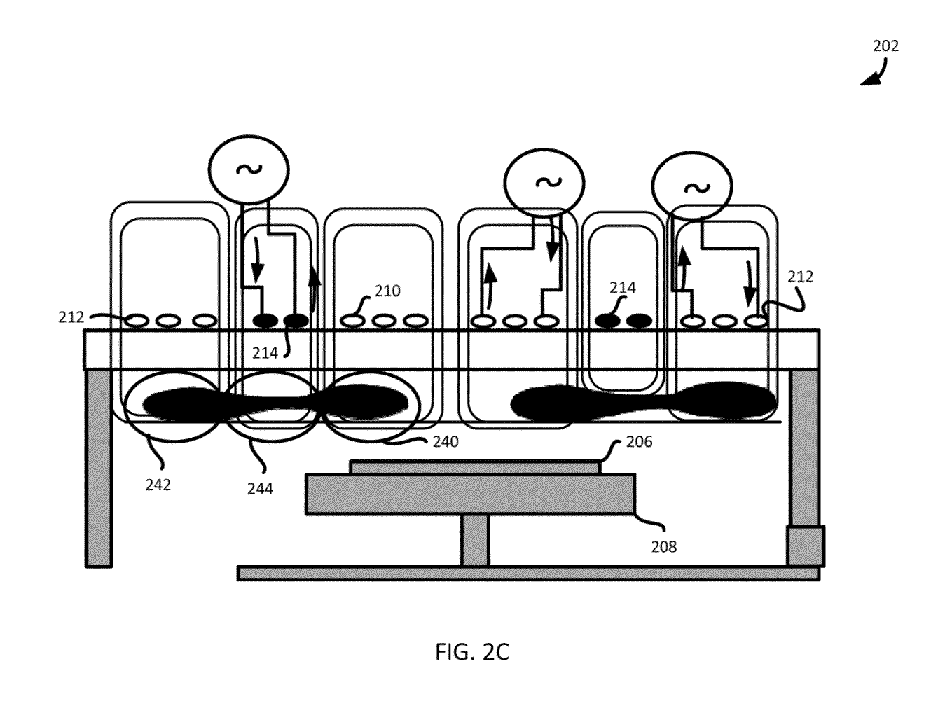

The features and advantages of embodiments of the invention may be better understood with reference to the figures and discussions that follow. FIG. 2A shows a simplified representation of the cut-away side view of relevant components of an ICP chamber 202 of a plasma processing system (which may have multiple chambers of the same or different types). In FIG. 2A, there is shown a dielectric window 204, which is typically disposed above a substrate 206 (see FIG. 2B) while the substrate is supported by work piece holder 208.

There is shown a first/center RF coil 210 disposed above dielectric window 204, which is concentric with a second/edge RF coil 212 also disposed above dielectric window 204. A third/mid RF coil 214 is disposed concentrically with coils 210/212 above dielectric window 204 and in between first/center RF coil 210 and second/edge RF coil 212. As the term is employed herein, third/mid RF coil 214 is considered “between” first/center RF coil 210 and second/edge RF coil 212 if it is disposed, in the x-y plane that is parallel to the plane of dielectric window 204, between the outer radius 220 of second (outer) RF coil 212 and the inner radius 222 of the first (inner) RF coil 210. The term “between” covers both the case where third/mid RF coil 214 overlaps one or both of first/center RF coil 210 and second/edge RF coil 212 when projected onto the aforementioned x-y plane as well as the case where third/mid RF coil 214 does not overlap with either of first/center RF coil 210 or second/edge RF coil 212 when projected onto the aforementioned x-y plane. Also as will be discussed later herein, there is no requirement (although such embodiment is possible and covered herein) that third/mid RF coil 214 be coplanar with one or both of first/center RF coil 210 and second/edge RF coil 214.

In one or more embodiments of the invention, the RF current provided to first/center and second/edge RF coils 210 and 212 by RF power supplies 230 and 232 are clockwise when viewed from the top of chamber 202 while the RF current provided to third/mid RF coil 214 by RF power supply 234 is counter-clockwise. Alternatively, the RF current provided to first/center and second/edge RF coils 210 and 212 are counter-clockwise when viewed from the top of chamber 202 while the RF current provided to third/mid RF coil 214 is clockwise. RF power supplies 230 and 232 may also be implemented as a single RF power supply having a splitter, for example. Further, RF power supplies 230, 232, and 234 may be implemented as a single power supply having circuitry for splitting the output RF current and reversing and/or changing the phase of one of the splitted output RF currents, for example.

Also, only a single coil 214 is shown disposed between first/center RF coil 210 and second/edge RF coil 212 in the example of FIG. 2A. In one or more embodiments, an RF coil set comprising two concentric RF coils may be disposed between first/center RF coil 210 and second/edge RF coil 212, with the RF current in those two concentric coils running in the same direction but opposite to the direction of the RF currents in first/center RF coil 210 and second/edge RF coil 212. In one or more embodiments, two concentric RF coils may be disposed between first/center RF coil 210 and second/edge RF coil 212, with the RF current in those two concentric coils running in the same direction but opposite to the direction of the RF currents in first/center RF coil 210 and second/edge RF coil 212.

In one or more embodiments, an RF coil set comprising three concentric RF coils may be disposed between first/center RF coil 210 and second/edge RF coil 212, with the RF currents in those three concentric coils running in alternate directions. In one or more embodiments, an RF coil set comprising four concentric RF coils may be disposed between first/center RF coil 210 and second/edge RF coil 212, with the RF currents in two adjacent RF coils of the coil set running in one direction and the RF currents in another two adjacent RF coils of the coil set running in the opposite direction, preferably counter to the direction of the RF current running in first/center RF coil 210 or second/edge RF coil 212 if they are adjacent. In one or more embodiments, an RF coil set comprising multiple concentric RF coils may be disposed between first/center RF coil 210 and second/edge RF coil 212, with the RF currents in those multiple concentric coils running in alternate directions in an interleaved fashion. The point is the RF current/currents in the coils of the coil set is configured to reduce or flatten or spread out the power distribution profile attributable to the additive effect of the magnetic flux lines from first/center RF coil 210 and second/edge RF coil 212, both of which have RF currents running in the same direction.

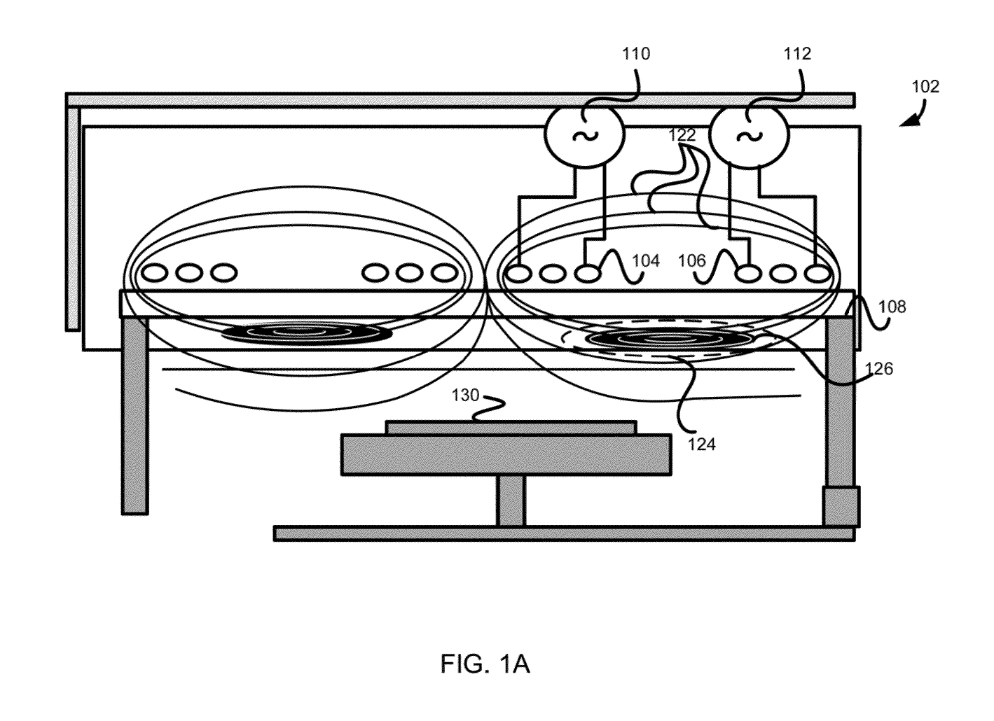

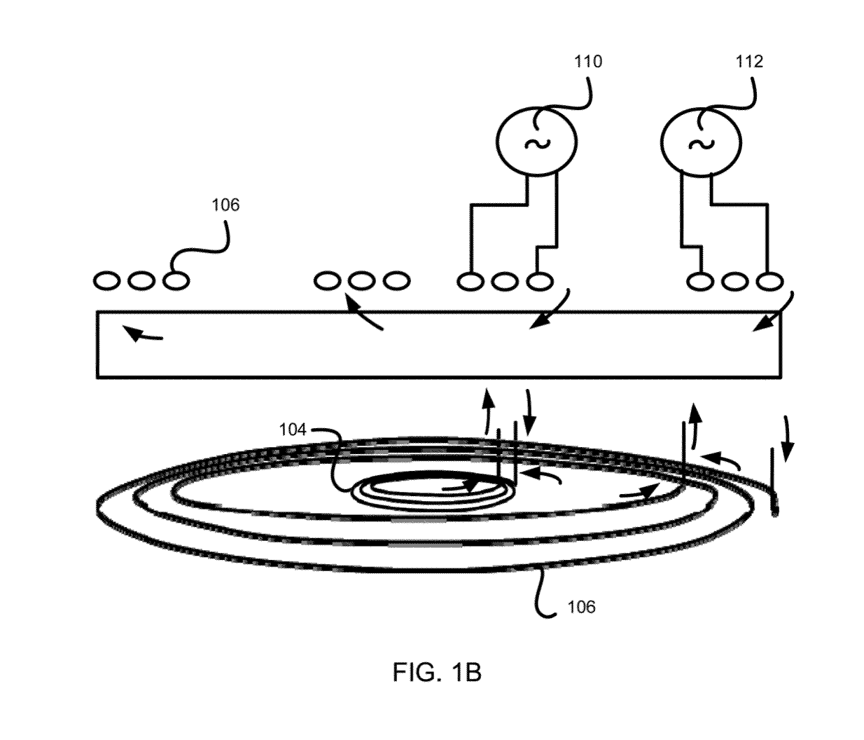

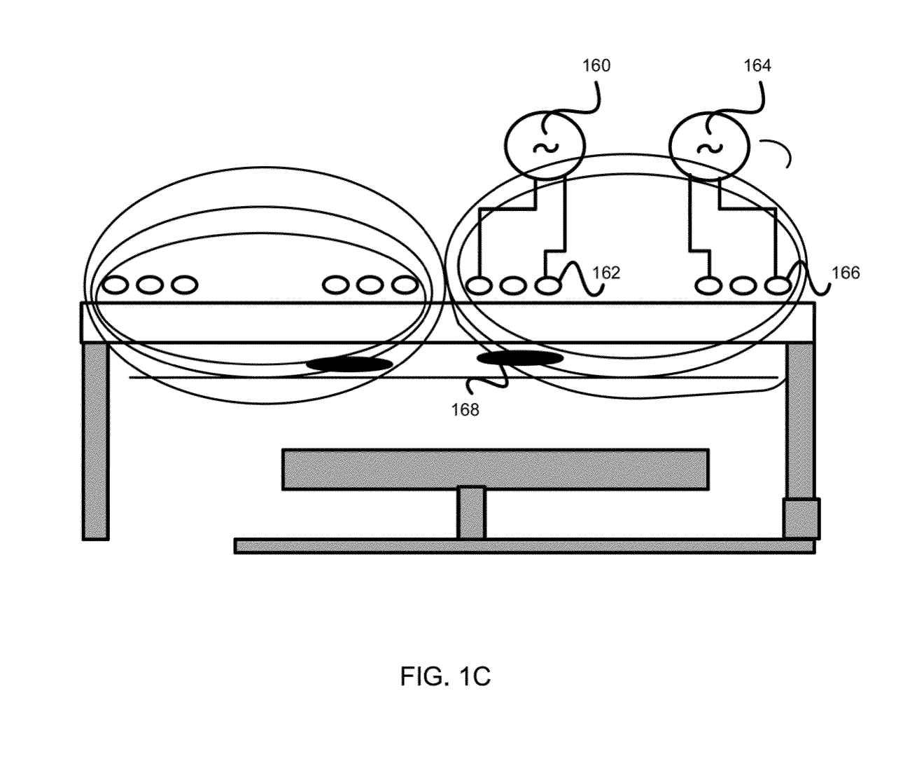

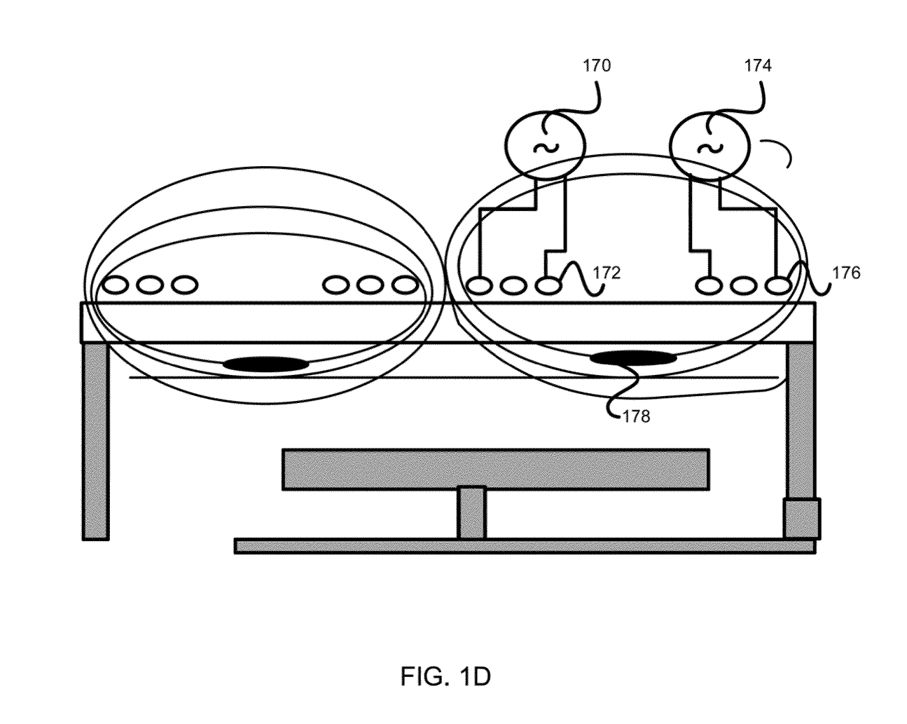

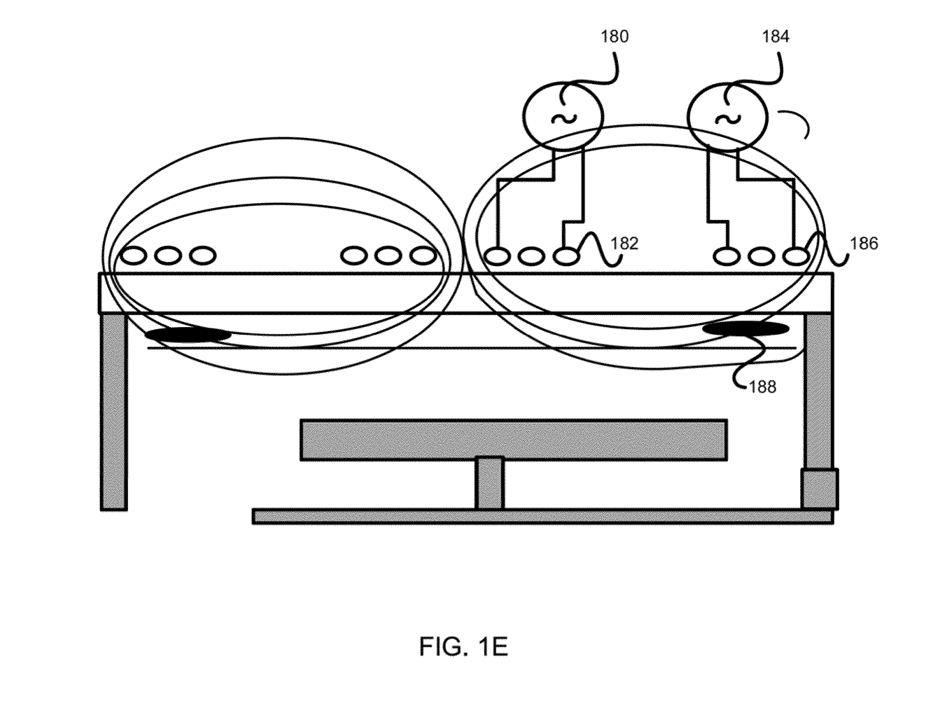

FIG. 2C shows in a conceptual manner the effect of providing third/mid RF coil 214 a counter RF current, which is in opposite direction with the RF currents supplied to first/center RF coil 210 and second/edge RF coil 212. In the absence of third/mid RF coil 214 and its counter current, the power deposition profile is additive from same-direction RF currents in first/center RF coil 210 and second/edge RF coil 212. As such, the plasma density (ion density) in region 244 would have been at least as much as the ion density in region 240 under first/center RF coil 210 or the ion density in region 242 under second/edge RF coil 212. Instead, the presence of third/mid RF coil 214 between first/center RF coil 210 and third/mid RF coil 214 causes the plasma fluxes from first/center RF coil 210 and second/edge RF coil 212 to become less coupled (or more decoupled), effectively spreading out the plasma flux over a greater area in the x-y plane that is parallel to the plane of the substrate. Conceptually speaking, the donut-shaped plasma cloud of prior art FIG. 1A is flattened in the z direction and caused to spread out more in the x-y plane, thereby effectively reducing the process non-uniformity caused by undue localized plasma over portions of the substrate.

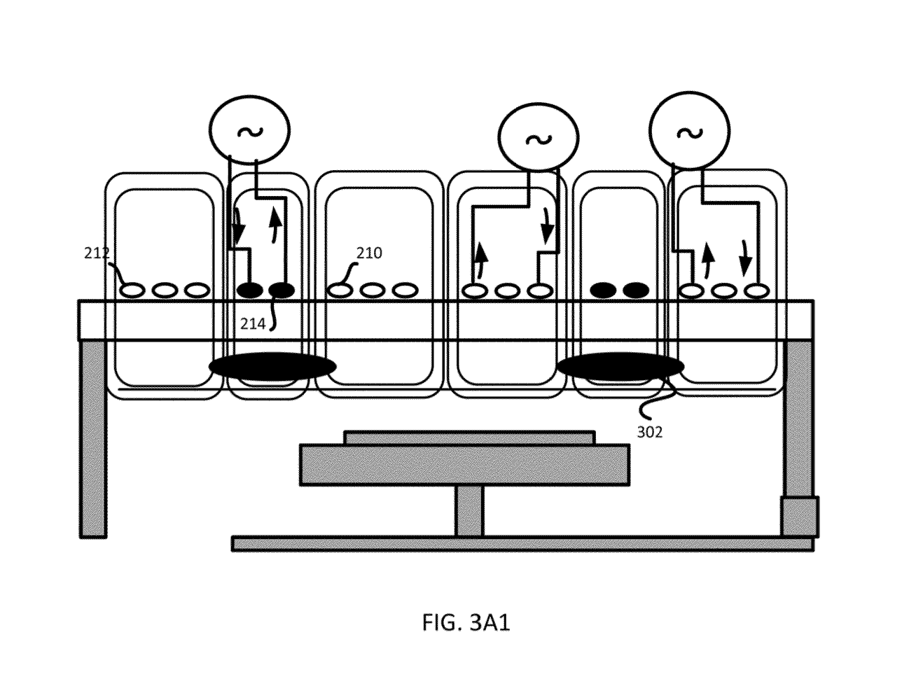

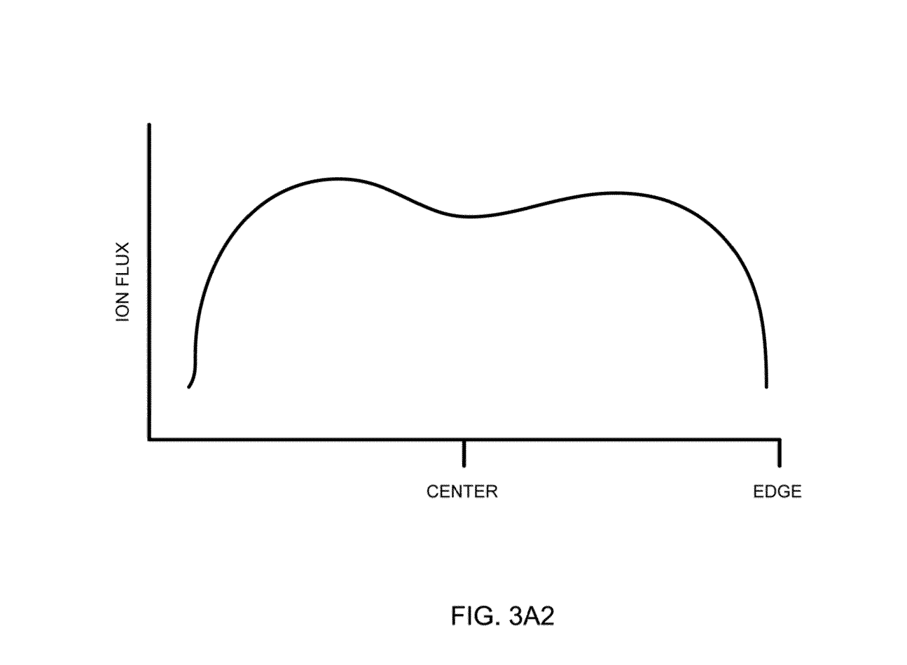

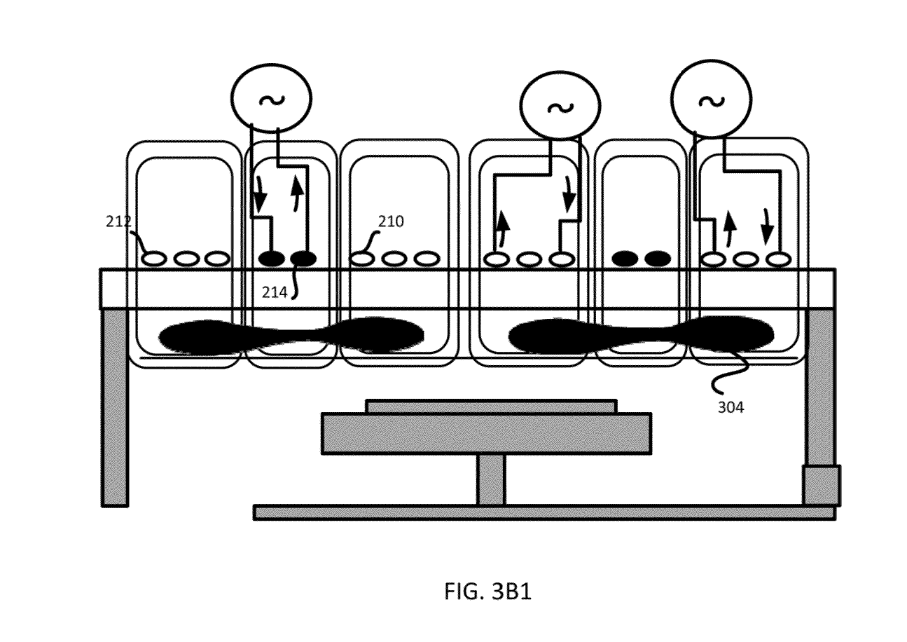

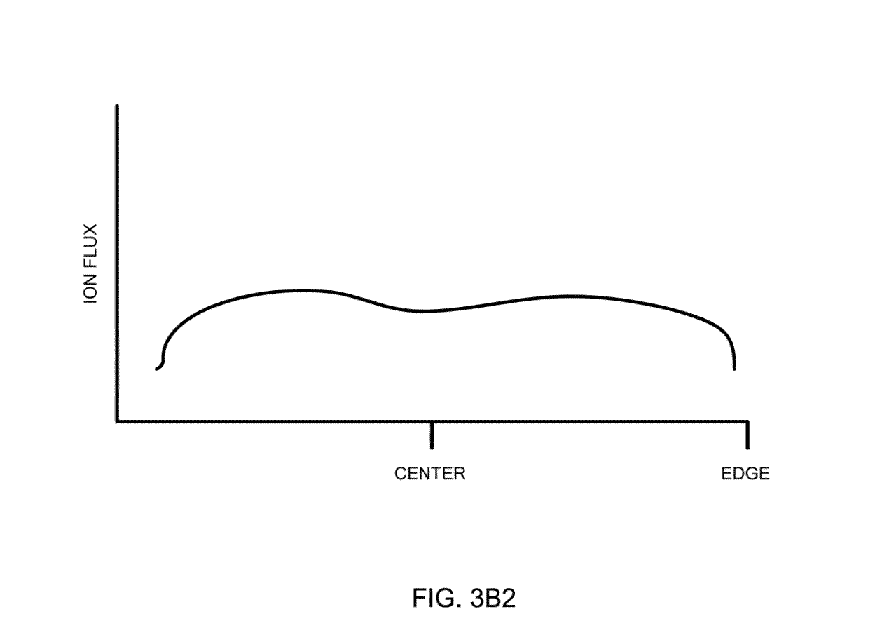

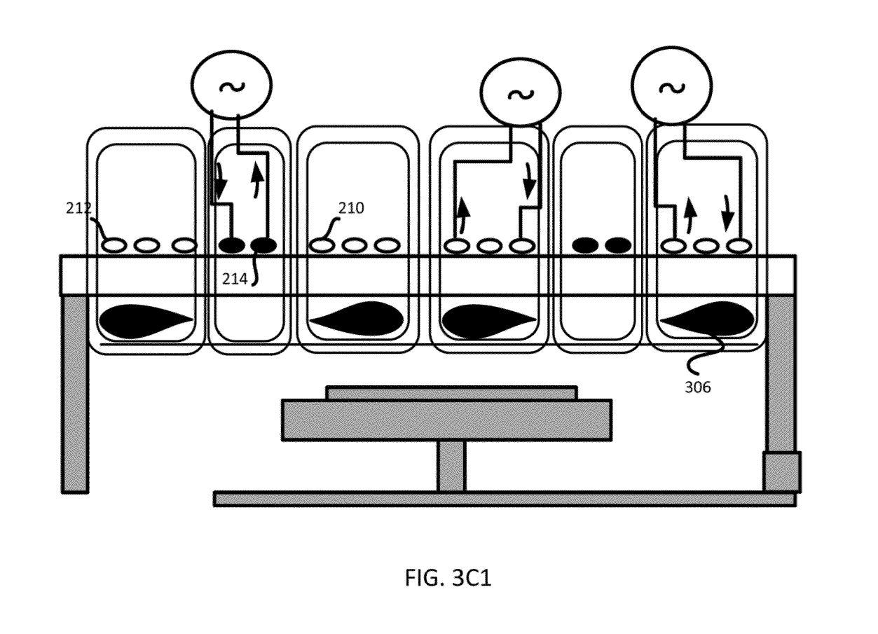

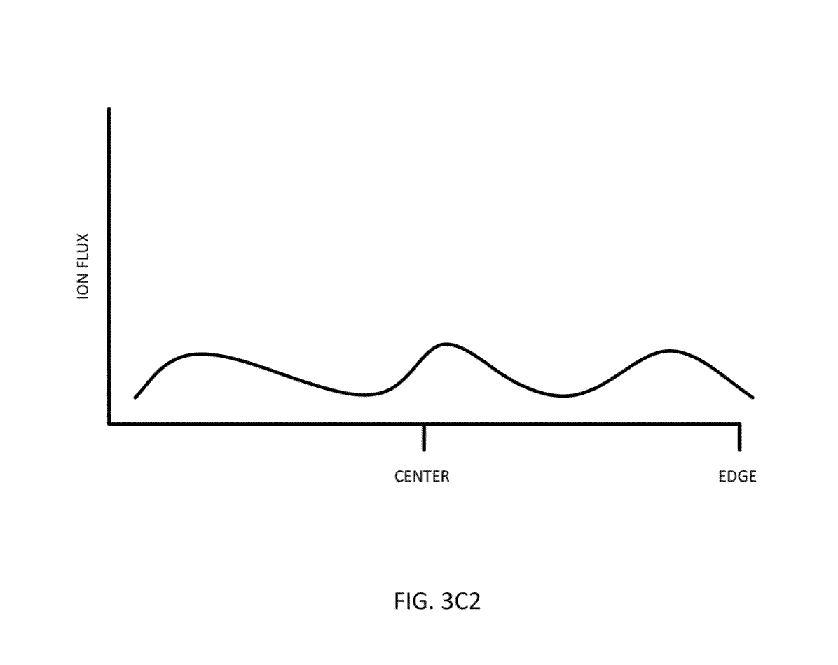

FIGS. 3A1 and 3A2 illustrate the effect on the plasma when the RF power level to the third/mid RF coil 214 is relatively low compared to the RF power level provided to the first/center RF coil 210 and second/edge RF coil 212. In this case, the plasma 302 attributable to first/center RF coil 210 and second/edge RF coil 212 is additive and highly coupled. A high degree of process non-uniformity from the substrate center to the substrate edge is likely. This is shown graphically in FIG. 3A2, which plots the ion density across the substrate. In FIG. 3A2, plasma density is higher mid-radius (in between the center the substrate and the edge of the substrate) and lower at the center and edge of the substrate.

FIGS. 3B1 and 3B2 illustrate the effect on the plasma when the RF power level to the third/mid RF coil 214 is at roughly the same power level compared to the RF power level provided to the first/center RF coil 210 and second/edge RF coil 212. In this case, the plasma 304 attributable to first/center RF coil 210 and second/edge RF coil 212 is more decoupled and the plasma cloud is spread over a larger area in the x-y direction, with less localized concentration mid-radius of the substrate. This is shown graphically in FIG. 3B2, which plots the ion density across the substrate.

FIGS. 3C1 and 3C2 illustrate the effect on the plasma when the RF power level to the third/mid RF coil 214 is relatively high compared to the RF power level provided to the first/center RF coil 210 and second/edge RF coil 212. In this case, the plasma 306 attributable to first/center RF coil 210 and second/edge RF coil 212 is highly decoupled. This is shown graphically in FIG. 3C2, which plots the ion density across the substrate. In FIG. 3C2, plasma density is lower mid-radius (in between the center the substrate and the edge of the substrate) and higher at the center and edge of the substrate.

As can be seen in FIGS. 3A1, 3A2, 3B1, 3B2, 3C1, and 3C2, adjusting the counter-current. RF power level provided to the third/mid RF coil 214 has a profound effect on the power deposition profile. It should be noted that it is possible, alternatively or additionally, to adjust the RF power level provided to first/center RF coil 210 or second/edge RF coil 212 to tune the plasma deposition profile as needed to achieve the desired process uniformity across the substrate surface.

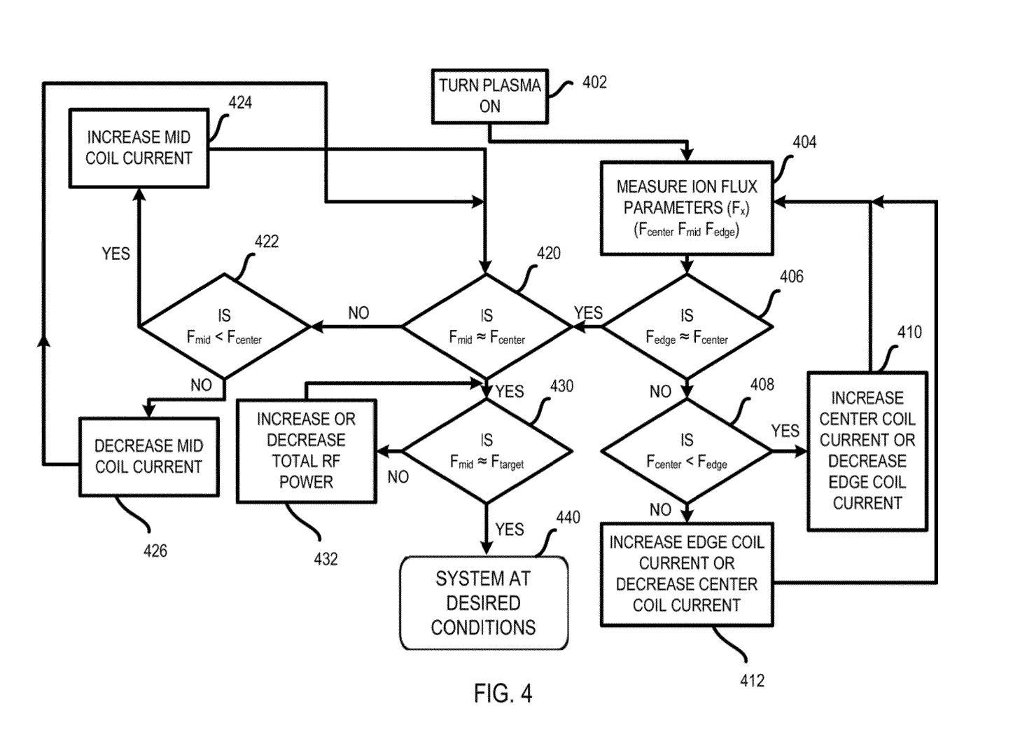

FIG. 4 shows, in accordance with an embodiment, a method for adjusting the power deposition profile in an ICP chamber. In one or more embodiments; the power deposition profile can be adjusted automatically in-situ in response to sensor measurements as mentioned earlier. In other embodiments, the power deposition profile can be adjusted in the factory responsive to metrology measurements made on test substrates and the power deposition profile may be adjusted to come up with the desired recipe for production.

In step 402, the power is turned on. In step 404, the ion flux parameters are measured by the sensor(s) and/or derived from chamber parameter measurements from the sensor(s). By way of example, sensors such as planar ion flux probes that are responsive to either the thermal energy or the RF current created by ions that are accelerated from the plasma to the wafer surface may be employed. The localized ion fluxes are then ascertained in step 404.

In steps 406, the ion flux under the center RF coil (first RF coil 210) and the ion flux under the edge RF coil (second RF coil 212) are compared. Iterating through steps 406, 408, 410, and 412, the RF current to the center RF coil (first RF coil 210) or the edge RF coil (second RF coil 212) is increased until the ion fluxes under them are determined to be equal in step 406.

Once the ion flux under the center RF coil (first RF coil 210) and the ion flux under the edge RF coil (second RF coil 212) are deemed equal, the process moves to step 420 to compare the ion flux under the center RF coil (first RF coil 210) and the ion flux under the mid RF coil (third RF coil 214).

Iterating through steps 420, 422, 424, and 426, the RF current to the mid RF coil (third RF coil 214) is increased or decreased until the ion fluxes under the center RF coil (first RF coil 210) and the ion flux under the mid RF coil (third RF coil 214) are determined to be equal in step 420.

Once the ion flux under the center RF coil (first RF coil 210) and the ion flux under the mid RF coil (third RF coil 214) are deemed equal, the process moves to step 430 to compare the ion flux under the mid RF coil (third RF coil 214) with a target ion flux. Iterating through steps 430 and 432, the RF power to all RF power supplies are increased or decreased together until the ion flux under the mid RF coil (third RF coil 214) is deemed equal to the predefined target ion flux (step 430), in which case the adjustment cycle of FIG. 4 is considered finished (step 440).

FIG. 5 shows a simplified diagram of an ICP chamber which employs sensor measurements of chamber parameters reflecting localized ion fluxes as feedback signals to automatically change the RF currents provided to the mid RF coil (third RF coil 214) and/or center RF coil (first RF coil 210) and/or edge RF coil (second RF coil 212). In FIG. 5, three sensors 510, 512, and 514 are shown disposed in different positions to measure parameters which may then be used to obtain or approximate the ion fluxes across the substrate. These measurements are collected by sensor circuit 520, which are then provided to a controller 530 for controlling RF power supplies 230, 232 and/or 234 to tune the power deposition profile.

Although adjusting the RF current power level to the mid RF coil (third RF coil 214) and/or the center RF coil (first RF coil 210) and/or the edge RF coil (second RF coil 212) has been discussed in the examples bus far as a means to tune the power deposition profile and improve process uniformity, it should be noted that it is possible to change, alternatively or additionally in one or more embodiments, the RF current phase to the mid RF coil (third RF coil 214) and/or the center RF coil (first RF coil 210) and/or the edge RF coil (second RF coil 212) as a means and method to tune the power deposition profile and improve process uniformity. Likewise, it is possible to change, alternatively or additionally in one or more embodiments, the RF frequency to the mid RF coil (third RF coil 214) and/or the center RF coil (first RF coil 210) and/or the edge RF coil (second RF coil 212) as a method and means to tune the power deposition profile and improve process uniformity.

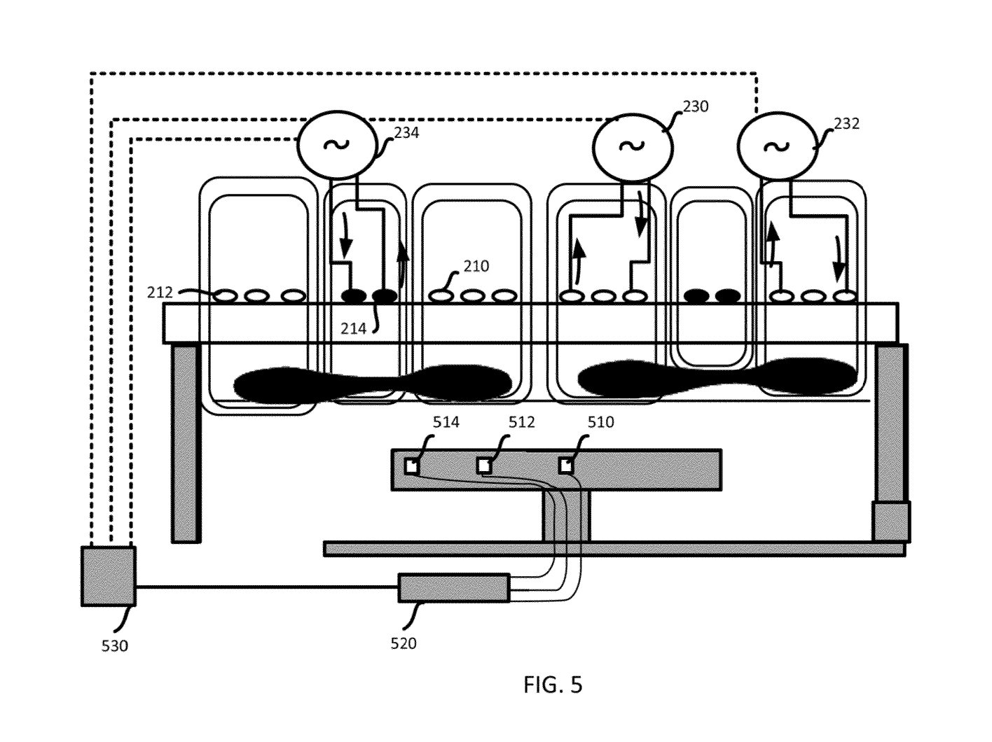

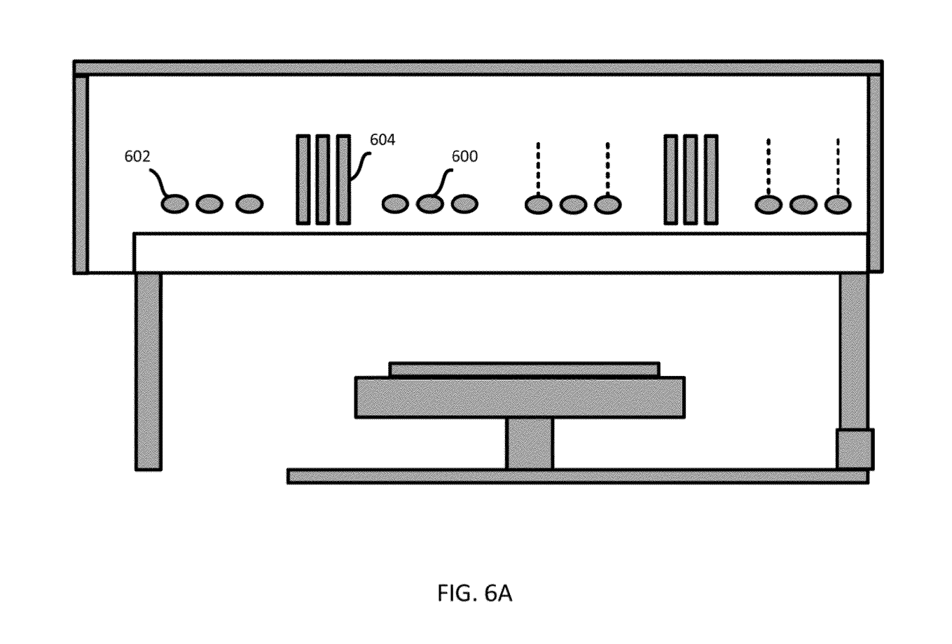

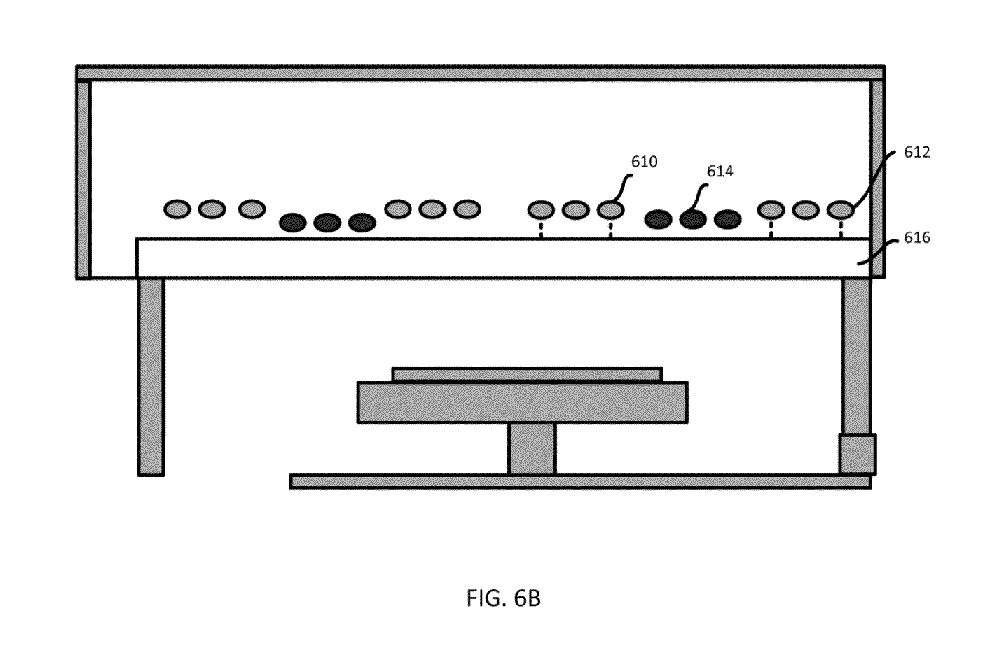

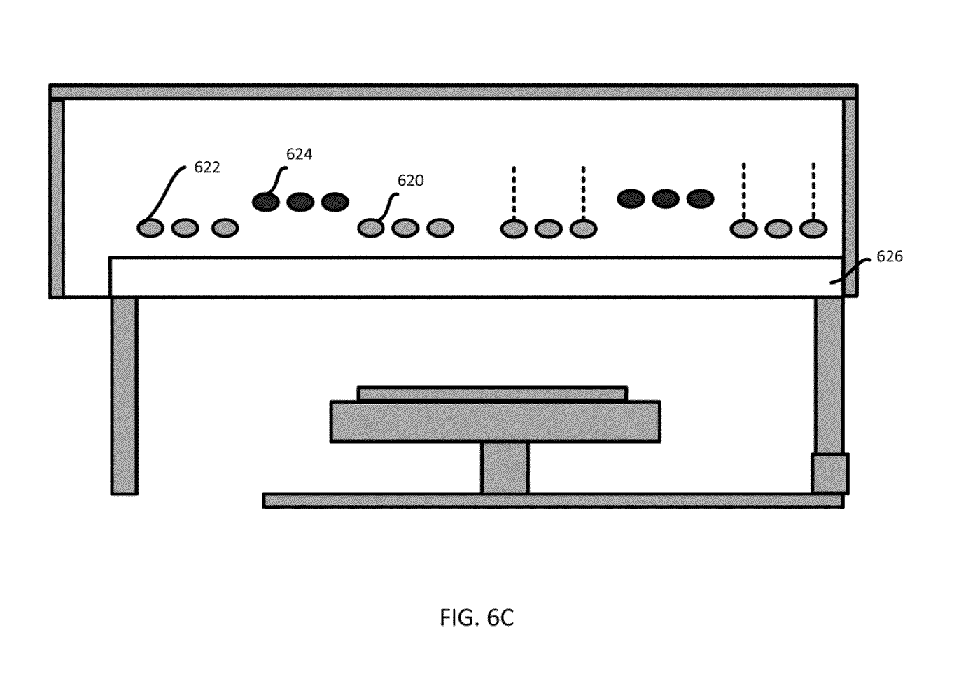

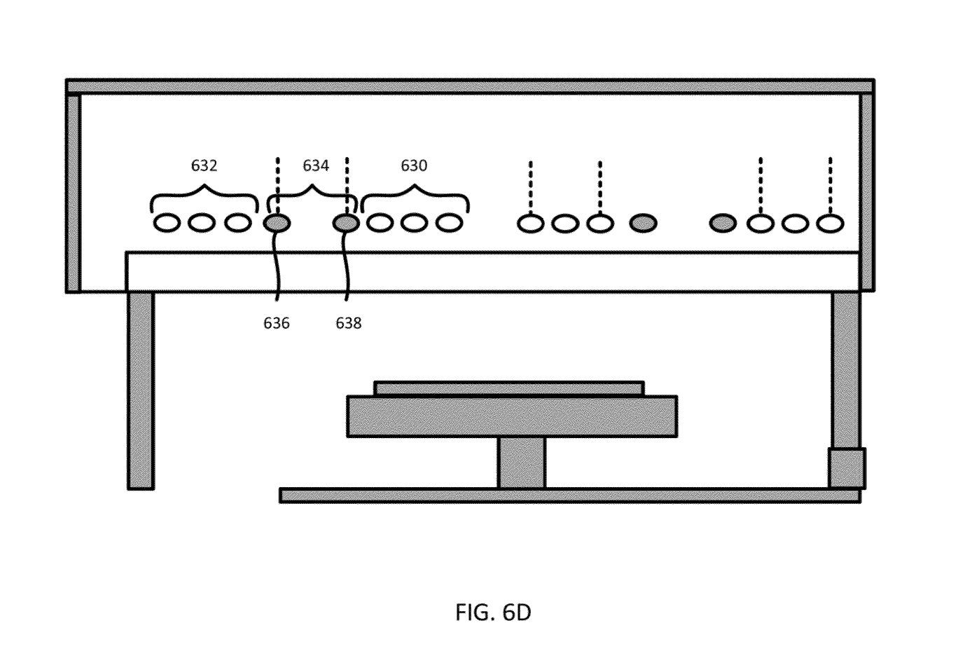

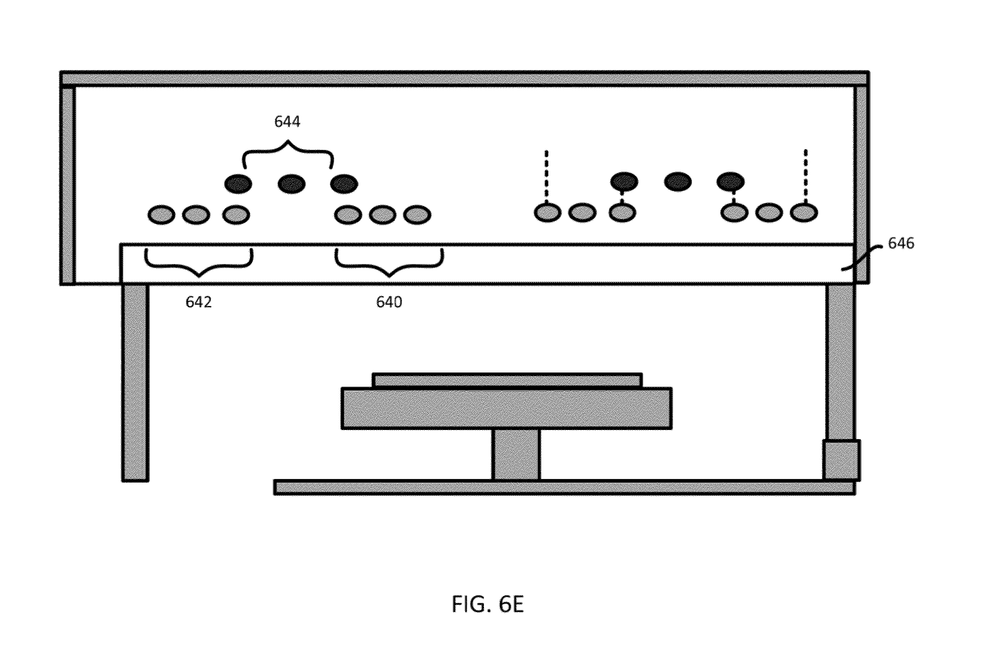

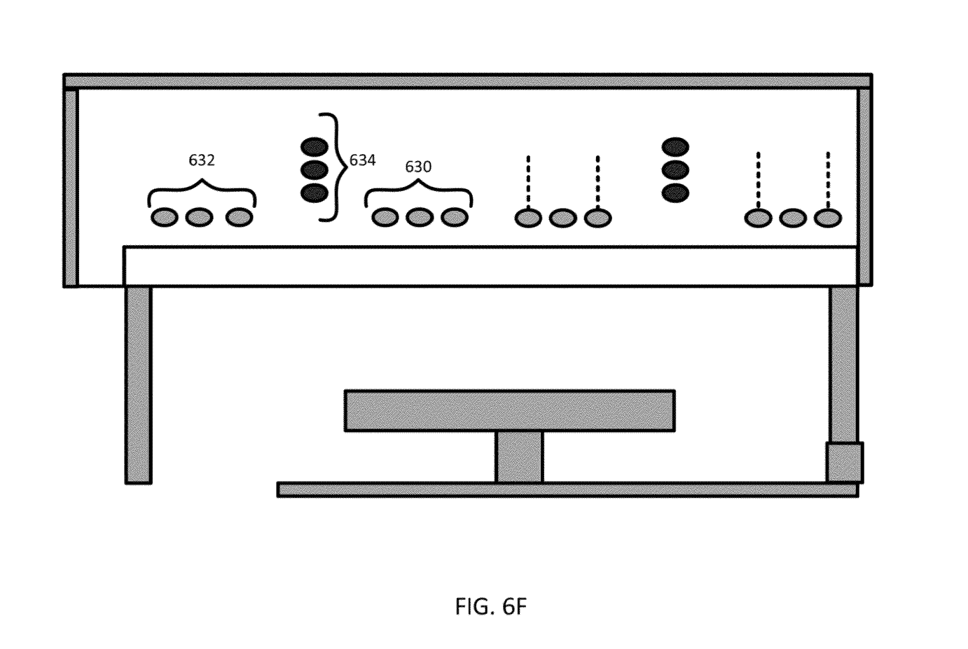

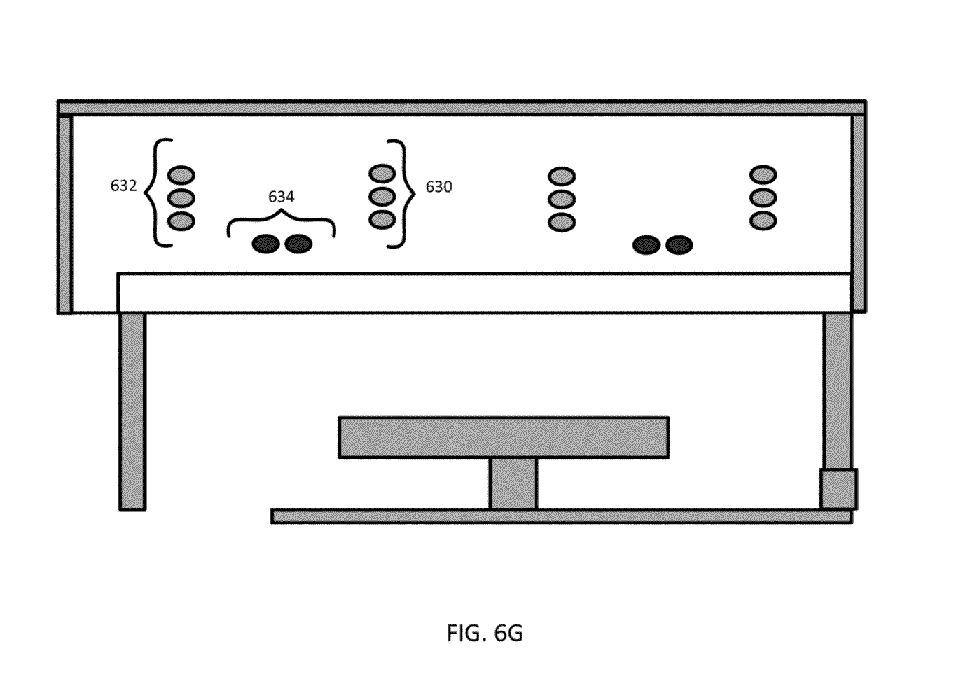

In one or more embodiments, the configuration and/or the relative positions of the RF coils may be changed to tune the power deposition profile and to improve process uniformity across the wafer. FIG. 6A shows an example where the mid RF coil (third RF coil 604) is substantially taller than the center RF coil and/or with the edge RF coil. Advantages of using different aspect ratio coil (height of turn relative to turn to turn separation) include the ability to concentrate the magnetic flux lines created by the mid RF coil in the region between the center and edge coils. In this case, the mid RF coil (third RF coil 604) is shown to be coplanar with the center RF coil (first RF coil 600) and/or the edge RF coil (second RF coil 602) but this co planarity is not an absolute requirements in some chambers.

FIG. 6B shows an example where the mid RF coil (third RF coil 614) is non-coplanar with the center RF coil (first RF coil 610) and/or with the edge RF coil (second RF coil 612). Also, the mid RF coil (third RF coil 614) is lower (closer to the plane of dielectric window 616) compared to the center RF coil (first RF coil 610) and/or the edge RF coil (second RF coil 612). In FIG. 6B, the center RF coil (first RF coil 610) and/or the edge RF coil (second RF coil 612) are coplanar but this co planarity is not an absolute requirements in some chambers.

FIG. 6C shows an example where the mid RF coil (third RF coil 624) is non-coplanar with the center RF coil (first RF coil 620) and/or with the edge RF coil (second RF coil 622). Also, the mid RF coil (third RF coil 624) is higher (further away from the plane of dielectric window 626) compared to the center RF coil (first RF coil 620) and/or the edge RF coil (second RF coil 622). In FIG. 6C, the center RF coil (first RF coil 620) and/or the edge RF coil (second RF coil 622) are coplanar but this co planarity is not an absolute requirements in some chambers.

FIG. 6D shows an example where the mid RF coil (third RF coil 634) is not disposed equidistant from the center RF coil (first RF coil 630) and/or the edge RF coil (second RF coil 632). In this FIG. 6D, turn 636 of the mid RF coil (third RF coil 634) is moved closer to edge RF coil (second RF coil 632) while turn 638 of the mid RF coil (third RF coil 634) is moved closer to center RF coil (first RF coil 630). In this case, the mid RF coil (third RF coil 634) is shown to be coplanar with the center RF coil (first RF coil 630) and/or the edge RF coil (second RF coil 632) but this co planarity is not an absolute requirements in some chambers.

FIG. 6E shows an example where the mid RF coil (third RF coil 644) is non-coplanar with the center RF coil (first RF coil 640) and/or with the edge RF coil (second RF coil 642) and some overlapping exists between the mid RF coil (third RF coil 644) and the center RF coil (first RF coil 640) and/or with the edge RF coil (second RF coil 642). Also, the mid RF coil (third RF coil 644) is higher (further away from the plane of dielectric window 646) compared to the center RF coil (first RF coil 640) and/or the edge RF coil (second. RF coil 642). As an alternative embodiment to FIG. 6E, the mid RF coil (third RF coil 644) may be disposed lower (closer to the plane of dielectric window 646) compared to the center RF coil (first RF coil 640) and/or the edge RF coil (second RF coil 642). In FIG. 6E, the center RF coil (first RF coil 640) and/or the edge RF coil (second RF coil 642) are coplanar but this co planarity is not an absolute requirements in some chambers.

FIG. 6F shows an example where the mid RF coil (third RF coil 634) is a solenoid-wound coil while center RF coil (first RF coil 630) and/or edge RF coil (second RF coil 632) are planar coils. Again, co-planarity among the RF coils of FIG. 6F is not an absolute requirement but may be implemented if desired.

FIG. 6G shows an example where the mid RF coil (third RF coil 634) is a planar coil while center RF coil (first RF coil 630) and/or edge RF coil (second. RF coil 632) are solenoid-wound coils. Again, co-planarity among the RF coils of FIG. 6G is not an absolute requirement but may be implemented if desired.

Alternative shapes and/or positions of the RF coils are also possible. For example, it is contemplated that in one or more embodiments, the third/mid RF coil may be non-planar and may be hat-shaped or have the shape of a truncated cone (either right side up or inverted). Alternatively or additionally, parts or the entire third/mid RF coil may be embedded in the dielectric window in one or more embodiments. Additionally, non-planar shapes or recess cavities may be incorporated in the dielectric window in order to accommodate the non planar arrangement or relative positions of the RF coils while maintaining a desired distance between the coils and the plasma.

Further, as mentioned, the position of the various RF coils and specifically the position of the third/mid RF coil relative to the other RF coils may be automatically changed using an appropriate actuator mechanism responsive to sensor measurements to achieve in-situ tuning of the power deposition profile in order to improve process uniformity across the substrate. For example, an actuator may be coupled to the mid/third RF coil to change its position relative to the first/center RF coil and/or relative to the second/edge RF coil. Alternatively or additionally, an actuator may be coupled to the first/center RF coil to change its position relative to the mid/third RF coil and/or relative to the second/edge RF coil. Alternatively or additionally, an actuator may be coupled to the second/edge RF coil to change its position relative to the mid/third RF coil and/or relative to the first/center RF coil.

As can be appreciated from the foregoing, embodiments of the invention advantageously improve process uniformity by providing multiple additional control knobs to tune the power deposition profile of the RF power from the various RF coils onto the plasma. By providing a concentric RF coil set between the first/center RF coil and the second/edge RF coil and providing a counter-current in the RF coil set (which may include one or more concentric RF coils and may carry currents in different directions but have at least one RF coil carrying the counter-current), the additive effect of the magnetic fluxes from the first/center RF coil and the second/edge RF coil is reduced and their plasma fluxes are decoupled to achieve a more even ion density profile across the wafer. Changing the RF phase and/or RF coil position are/is additional control knob(s) that may be provided to additionally or alternatively tune the power deposition profile and to improve process uniformity across the substrate.

Although some embodiments have been described using the apparatus, the invention also covers methods for making and/or operating the apparatus in its various embodiments. While different features may be discussed in different embodiments for ease of understanding, there is no implication that these features are mutually exclusive in all cases. Although it is permissible that a chamber may have only one of the disclosed features, different combinations of features disclosed in various embodiments herein may be combined in a single chamber or in a plasma processing system to advantageously improve plasma processing.

While this invention has been described in terms of several preferred embodiments, there are alterations, permutations, and equivalents, which fall within the scope of this invention. Although various examples are provided herein, it is intended that these examples be illustrative and not limiting with respect to the invention. Also, the title and summary are provided herein for convenience and should not be used to construe the scope of the claims herein. Further, the abstract is written in a highly abbreviated form and is provided herein for convenience and thus should not be employed to construe or limit the overall invention, which is expressed in the claims. If the term “set” is employed herein, such term is intended to have its commonly understood mathematical meaning to cover zero, one, or more than one member. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A plasma processing system having at least a plasma processing chamber for processing substrates, comprising:
a work piece holder for supporting said substrate during said processing;
a dielectric window disposed above said work piece holder;
a first RF coil disposed above said dielectric window;
a second RF coil disposed concentrically relative to said first RF coil, said second RF coil also disposed above said dielectric window; and
an RF coil set including at least a third RF coil disposed concentrically relative to said first RF coil and said second RF coil, said third RF coil disposed between said first RF coil and said second RF coil, wherein, a first RF current supplied to said first RF coil and a second RF current supplied to said second RF coil are both in a first direction, and a third RF current supplied to said third RF coil is in a second direction opposite said first direction.

2. The plasma processing system of claim 1 wherein said first RF coil and said second RF coil are coplanar and wherein said third RF coil is non-coplanar with respect to said, first RF coil and said second RF coil.

3. The plasma processing system of claim 2 wherein said third RF coil is disposed closer to a plane of said dielectric window than said first RF coil.

4. The plasma processing system of claim 2 wherein said third RF coil is disposed further from a plane of said dielectric window than said first RF coil.

5. The plasma processing system of claim 1 wherein said RF coil set further includes a fourth RF coil also disposed concentrically relative to said first RF coil and said second RF coil, said fourth RF coil disposed between said first RF coil and said second RF coil, and a fourth RF current supplied to said fourth RF coil is in the second direction opposite said first direction.

6. The plasma processing system of claim 1 wherein said third RF coil is a non-planar coil.

7. The plasma processing system of claim 1 wherein said first RF coil and said second RF coil are non-coplanar and wherein said third RF coil is non-coplanar with respect to said first RF coil and said second RF coil.

8. The plasma processing system of claim 1 further comprising:
a set of sensors having at least one sensor for sensing one or more chamber parameters reflective of localized ion densities of said plasma;
means for automatically changing, while said substrate is in-situ and during said processing, at least one of a RF power supplied to said third RF coil, RF phase of said third RF current supplied to said third RF coil, and position of said third RF coil relative to one of said first RF coil and second RF coil responsive to measurements from said set of sensors.

9. The plasma processing system of claim 8 wherein said set of sensors comprise a plurality of fixed sensors.

10. The plasma processing system of claim 8 wherein said set of sensors comprise at least one movable sensor.

11. The plasma processing system of claim 1 further comprising a single RF power supply coupled to provide said first RF current, said second RF current, and said third RF current respectively to said first RF coil, said second RF coil, and said third RF coil.

12. The plasma processing system of claim 1 wherein said means for changing includes an actuator for moving said third RF coil in a direction orthogonal to a plane of said dielectric window.

13. The plasma processing system of claim 1 further comprising:
a set of sensors having at least one sensor for sensing one or more chamber parameters reflective of localized ion densities of said plasma;
means for automatically changing, while said substrate is in-situ and during said processing, an RF power level of at least one of said first RF current, second RF current, and third RF current responsive to measurements from said set of sensors.

14. The plasma processing system of claim 1 further comprising:
a set of sensors having at least one sensor for sensing one or more chamber parameters reflective of localized ion densities of said plasma;
means for automatically changing, while said substrate is in-situ and during said processing, a phase of at least one of said first RF current, second RF current, and third RF current responsive to measurements from said set of sensors.

15. The plasma processing system of claim 1 wherein said first RF current supplied to said first RF coil and said second RF current supplied to said second RF coil are supplied from a single RF power supply through a splitter.

16. The plasma processing system of claim 1 further comprising:
a set of sensors having at least one sensor for sensing one or more chamber parameters reflective of localized ion densities of said plasma;
means for automatically changing, while said substrate is in-situ and during said processing, a frequency of at least one of said first RF current, second RF current, and third RF current responsive to measurements from said set of sensors.

17. The plasma processing system of claim 1 further comprising a first. RF power supply coupled to provide said first RF current to said first RF coil, a second RF power supply coupled to provide said second RF current to said second RF coil, and a third RF power supply coupled to provide said third RF current to said third RF coil.

18. A method for processing a substrate in a plasma processing system having at least a plasma processing chamber for processing said substrate, comprising:
providing a work piece holder for supporting said substrate during said processing;
providing a dielectric window disposed above said work piece holder;
providing a first RF coil disposed above said dielectric window;
providing a second RF coil disposed concentrically relative to said first RF coil, said second RF coil also disposed above said dielectric window; and
providing an RF coil set including at least a third RF coil disposed concentrically relative to said first RF coil and said second RF coil, said third RF coil disposed between said first RF coil and said second RF coil, wherein a first RF current supplied to said first RF coil and a second RF current supplied to said second RF coil are both in a first direction, and a third RF current supplied to said third RF coil is in a second direction opposite said first direction;
processing said substrate while energizing said first RF coil with said first RF current, said second RF coil with said second RF current, and said third RF coil with said third RF current.

19. The method of claim 18 wherein said first RF coil and said second RF coil are coplanar and wherein said third RF coil is non-coplanar with respect to said first RF coil and said second RF coil.

20. The method of claim 18 wherein said RF coil set further includes a fourth RF coil also disposed concentrically relative to said first RF coil and said second RF coil, said fourth RF coil disposed between said first RF coil and said second RF coil, and a fourth RF current supplied to said fourth RF coil is in the second direction opposite said first direction.

21. The method of claim 18 further comprising:
providing a set of sensors having at least one sensor for sensing one or more chamber parameters reflective of localized ion densities of said plasma;
automatically changing, while said substrate is in-situ and during said processing, at least one of a RF power supplied to said third RF coil, RF phase of said third RF current supplied to said third RF coil, and position of said third RF coil relative to one of said first RF coil and second RF coil responsive to measurements from said set of sensors.

22. The method of claim 18 further comprising:
providing a set of sensors having at least one sensor for sensing one or more chamber parameters reflective of localized ion densities of said plasma;
automatically changing, while said substrate is in-situ and during said processing, an RF power level of at least one of said first RF current, second RF current, and third RF current responsive to measurements from said set of sensors.

23. The method of claim 18 further comprising:
providing a set of sensors having at least one sensor for sensing one or more chamber parameters reflective of localized ion densities of said plasma;
means for automatically changing, while said substrate is in-situ and during said processing, a phase of at least one of said first RF current, second RF current, and third RF current responsive to measurements from said set of sensors.
